(19) United States
(12) Patent Application Publication
(10) Pub. No.: US 2017/0025478 A1
(43) Pub. Date: Jan. 26, 2017

(54) Organic Light-Emitting Component

(71) Applicant: OSRAM OLED GMBH, Regensburg (DE)

(72) Inventors: Thomas Wehlus, Lappersdorf (DE); Carola Diez, Regensburg (DE); Erwin Lang, Regensburg (DE); Nina Riegel, Tegernheim (DE); Daniel Riedel, Regensburg (DE)

(21) Appl. No.: 15/125,058

(22) PCT Filed: Mar. 17, 2015
(86) PCT No.: PCT/EP2015/055573

§ 371 Date: Sep. 9, 2016

(30) Foreign Application Priority Data
Mar. 18, 2014 (DE) 10 2014 103 675.1

(51) Int. Cl. H01L 27/32; H01L 51/52

(52) U.S. Cl. CPC H01L 27/322; H01L 51/5265; H01L 51/5253; H01L 51/5203

(57) ABSTRACT

An organic light-emitting component is disclosed. The organic light emitting component includes a substrate and at least one layer sequence arranged on the substrate and suitable for generating electromagnetic radiation. The at least one layer sequence may include at least one first electrode area arranged on the substrate, at least one second electrode area arranged on the first electrode area, a basic color unit arranged between the first electrode area and the second electrode area and a plurality of color units arranged between the basic color unit and the first or second electrode area, wherein the plurality of color units are arranged laterally offset to one another, and wherein the basic color unit and each of the plurality of color units respectively comprises at least one organic light-emitting layer.

This patent application is a national phase filing under section 371 of PCT/EP2015/055573, filed Mar. 17, 2015, which claims the priority of German patent application 10 2014 103 675.1, filed Mar. 18, 2014, each of which is incorporated herein by reference in its entirety.

### TECHNICAL FIELD

An organic light-emitting component is provided.

### BACKGROUND

In organic light-emitting diodes (OLEDs), only part of the generated light is directly coupled-out. The light generated in the active region can be assigned to various loss channels, such as in light being guided in the substrate, in a transparent electrode and in organic layers by wave conduction effects as well as in surface plasmons that can be generated in a metallic electrode. Said wave conduction effects particularly arise from a difference in the refractive index at the interfaces between individual layers and regions of an OLED. In known OLEDs, typically only a fourth of the light generated in the active region is coupled-out to the environment, such as the air, while approximately 25% of the generated light gets lost by wave conduction in the substrate, approximately 20% of the generated light gets lost by wave conduction in a transparent electrode and the organic layers, and approximately 30% gets lost by the generation of surface plasmons in a metallic electrode for the radiation.

Furthermore, the effects of the above-mentioned loss mechanisms are different depending on the observed spectral components of the radiated light. As a result, the loss in a first spectral subrange of the emitted light can be greater than in a second subrange. The organic layer stack of an OLED can be considered as a micro-cavity, with an organic light-emitting layer being embedded in said micro-cavity and light emission resulting from luminescence when applying an external voltage. The geometric boundary conditions of the micro-cavity lead to certain subranges of the emitted spectrum being suppressed or even completely cut-off, so that actually other subranges of the spectrum in the radiated light are emphasized. This may result in an undesired degradation of the color rendering index (CRI).

Influence of the distance of the organic light-emitting layer to the reflective electrode area is mentioned by way of example. When changing said distance by increasing or decreasing the layer thickness of the layers arranged there-between, position and width of spectral subranges suppressed in the radiated light will change, resulting in a different radiation characteristic of the component.

In order to increase the color rendering index, measures are known, for example, for adjusting and optimizing the spectrum of the radiated light by suitably positioning the light-emitting layer in the micro-cavity. Furthermore, the color rendering index can be increased by adding additional light-emitting layers that ensure additional emission in individual, limited wavelength ranges. However, manufacture is very elaborate and can be realized only by use of a cluster device. Moreover, this approach involves an increase of the required operating voltage.

### SUMMARY OF THE INVENTION

Embodiments of the invention provide an organic light-emitting component which has an improved color rendering index.

According to at least one embodiment, an organic light-emitting component comprises a substrate and at least one layer sequence arranged on the substrate and suitable for generating electromagnetic radiation. The layer sequence suitable for generating electromagnetic radiation comprises at least one electrode area arranged on the substrate, at least one second electrode area arranged on the first electrode area, a basic color unit between the first electrode area and the second electrode area, and a plurality of color units between the basic color unit and the first or second electrode area. Preferably, the plurality of color units is arranged between the basic color unit and the second electrode area.

As used herein, a layer or an element being arranged or applied “on” or “to” another layer or another element relates to a situation where said layer or said element is directly arranged in a direct mechanical and/or electrical contact on the other layer or the other element. It may furthermore relate to a situation where said layer or said element is indirectly arranged on or above the other layer or the other element. In this case, further layers and/or elements may be arranged between one and the other layer. The same applies to the arrangement of a layer or an element “between” two other layers or two other elements.

The color units are arranged laterally offset to one another. Both the basic color unit and each of the color units respectively comprise at least one organic light-emitting layer.

Here and below, color unit particularly refers to an organic functional layer stack comprising organic functional layers, said stack comprising at least one organic light-emitting layer. Lateral direction particularly refers to a direction parallel to a main extension plane of the substrate and/or at least one of the organic light-emitting layers. In analogy, vertical direction particularly refers to a direction perpendicular to a main extension plane of the substrate and/or one of the organic light-emitting layers.

As a result of the fact that the plurality of color units is arranged laterally offset to one another, the individual micro-cavities assigned to the respective color units can be adjusted individually in terms of their geometric boundary conditions, which is possible in a vertical stacking of the color units over one another only to a limited extent. Generally, the radiation of certain color components can be increased or reduced by a suitable selection of the color units and the micro-cavities assigned thereto, allowing the spectrum of the emitted light to be adjusted as desired. In particular, the color rendering index can be advantageously increased by the effects of the color units.

For example, a first sub-region of the component can be present in which the micro-cavity of a color unit is adjusted such that the above-described suppressing of a certain partial range of the emitted spectrum results. However, for compensation, a second sub-region of the component may be present in which the micro-cavity of another color unit is adjusted such that the same partial range of the emitted spectrum is suppressed less or not at all.

According to at least one further embodiment of the component, it is provided that the organic light-emitting layer of the basic color unit is designed for generating electromagnetic radiation of a first wavelength range and each of the organic light-emitting layers of the plurality of color units is designed for generating electromagnetic radiation of a wavelength range different from the first wavelength range.

According to at least one further embodiment of the component, it is provided that the organic light-emitting layers of the plurality of color units is designed for generating electromagnetic radiation of wavelength ranges that are different from one another.

According to at least one further embodiment of the component, it is provided that the wavelength ranges assigned to the basic color unit and to the plurality of color units do not overlap with one another.

According to at least one further embodiment of the component, it is provided that the distance of two neighboring color units from one another is less than 1 mm, in particular less than 0.1 mm. This way, an external observer won't feel uncomfortable because of the transitions between the different color units. In particular, each of the color units may have a diameter in the lateral direction that is less than 1 mm, in particular less than 0.1 mm.

According to at least one further embodiment of the component, it is provided that the color units are designed in the type of strips and arranged parallel to one another. However, the color units may also be arranged in a two-dimensional, particularly right-angled or hexagonal grid, for example.

According to at least one further embodiment of the component, it is provided that at least one additional basic color unit is arranged between the plurality of color units and the basic color unit, said addition basic color unit comprising at least one organic light-emitting layer. By multiply stacking basic color units vertically, the life of the component can be extended in many situations. Vertically stacking two basic color units, for example emitting red and green light, allows ensuring a relatively long basis service life and a suitable adjustment of the individual micro cavities of the plurality of color units allows generating a desired accentuation in certain color ranges, for example corresponding to blue light, for example.

According to at least one further embodiment of the component, it is provided that the plurality of color units is arranged between the basic color unit and at least one covering color unit, the latter comprising at least one organic light-emitting layer. This allows increasing the service life of the component just as well.

The electrode areas may each have a large-area design. This allows generating a large-area radiation of the light generated in the organic light-emitting layers—particularly in contrast to a display, in which the electrode areas are structured. As used herein, “large-area” can mean that the electrode areas have an area of equal to or greater than one square millimeter, preferably greater than or equal to one square centimeter and particularly preferably greater than one square decimeter.

According to at least one further embodiment of the component, the first and/or second electrode area has a translucent design. As used herein, “translucent” refers to a layer that is permeable to visible light. Herein, said translucent layer may be transparent, i.e. fully transparent, or at least partially light-scattering and/or light-absorbing, so that the translucent layer may be diffuse or milky, for example. Particularly preferably, a layer described herein to be translucent has a most transparent design so that particularly adsorption of light is as low as possible.

According to a further particularly preferred embodiment, the substrate has a translucent design and the first electrode area having the translucent design is arranged between the translucent substrate and the basic color unit, allowing light generated in the organic light-emitting layers to be radiated through the first electrode area and the translucent substrate. Such an organic light-emitting component can also be referred to as a so-called “bottom emitter”. For example, the substrate may comprise one or more materials in the form of a layer, a plate, a foil or a laminate, said materials selected from glass, quartz, synthetic material, metal, silicon wafer.

According to a further particularly preferred embodiment, the second electrode area has a translucent design, so that the generated light can be radiated through the second electrode area. Such an organic light-emitting component can also be referred to as a so-called “top emitter”. The organic light-emitting component may also be configured as a “bottom emitter” and “top emitter” at the same time.

Furthermore, an encapsulation arrangement may be disposed on top of the electrode areas and the plurality of color units. Said encapsulation unit may be configured in the form of a glass cover or, preferably, in the form of a thin film encapsulation.

According to at least one further embodiment of the component, it is provided that the color units have different heights. For example, the heights of the highest and the least high color unit, namely particularly the extensions of the highest and least high color unit in the vertical direction, can be different from one another by at least 5 nm, preferably by at least 10 nm, particularly preferably by at least 20 nm.

Alternatively or additionally, the organic light-emitting layers of the plurality of color units can each be arranged in different planes, namely particularly be spaced from one another not only laterally, but vertically as well. For example, two of the plurality of color units may comprise organic light-emitting layers, said layers having a distance of at least 5 nm, preferably at least 10 nm, particularly preferably at least 20 nm, in the vertical direction.

The above measures allow adjusting the individual micro cavities assigned to the respective color units individually in terms of their geometric boundary conditions, whereby radiation of certain color components can be increased or reduced and the spectrum of the emitted light can be adjusted as desired.

According to at least one further embodiment of the component, it is provided that the first electrode area or the second electrode area are designed to be reflective and the organic light-emitting layers of the plurality of color units each have different vertical distances to the first or second electrode areas that are designed to be reflective. As described above, the position and width of the spectral sub-ranges suppressed in the radiated light change with a variation of the distance between an organic light-emitting layer and the reflective first or second electrode area by increasing or reducing the layer thickness of the layers arranged therebetween. A suitable selection of the distances between the respective organic, light-emitting layers of the plurality of color units to the first or second electrode area of reflective design allows adjusting the individual micro-cavities assigned to the respective color units individually in terms of their geometric boundary conditions, whereby radiation of certain color components can be increased or reduced and the spectrum of the emitted light can be adjusted as desired.

According to another embodiment, the translucent electrode area is formed as anode and may thus serve as a hole-injecting material. The other electrode area, which is preferably designed to be reflective, is formed as a cathode then. As an alternative, the translucent electrode area can also be formed as a cathode and thus serve as an electron-injecting material. The other electrode area, which is preferably designed to be reflective, is formed as an anode then.

The translucent electrode area may comprise a transparent, conductive oxide or consist of a transparent, conductive oxide, for example. Transparent conductive oxides (TCOs) are transparent conductive materials, usually metal oxides such as zinc oxide, tin oxide, cadmium oxide, titanium oxide, indium oxide or indium tin oxide (ITO).

According to another embodiment, the reflective-design electrode area comprises a metal, which may be selected from aluminum, barium, indium, silver, gold, magnesium, calcium or lithium as well as compounds, combinations and alloys. Particularly preferably, the reflective electrode area has a reflectivity of equal to or greater than 80% in the visible spectral range.

The following specifications made in connection with the basic color unit also apply to the additional basic color unit or the covering color unit, unless explicitly indicated otherwise.

According to at least one further embodiment of the component, it is provided that the basic color unit and/or each of the color units in each case comprise a layer that conducts organic holes or that conducts organic electrodes.

According to at least one further embodiment of the component, it is provided that the color units comprise layers that conduct organic holes, in particular hole transport layers, or layers that conduct organic electrons, in particular electron transport layers, said layers each having a different thickness. Since the voltage drop at the hole-conducting layer or the electron-conducting layer depends on the layer thickness only to a minor extent, said layers are suitable for adjusting the properties of the micro-cavities, which can ensue sufficiently independent of the operating voltage. It is thus possible to achieve optimization of the micro-cavities by adjusting the thickness of said layers without affecting the electro-optical properties of the remaining layer stack of the respective color unit to a major extent.

According to at least one further embodiment of the component, it is provided that the color units comprise blocker layers, in particular electron and/or hole blocker layers, said layers each having a different thickness. Just as well, said layers are suitable for adjusting the properties of the micro-cavities, whereby, in addition, a shift of the respective emission zone can be achieved.

The organic functional layers of the basic color unit and/or of each of the color units, for example the hole-conducting layers, the organic light-emitting layers and the electron-conducting layers, may comprise organic polymers, organic oligomers, organic monomers, organic small non-polymer molecules or low-molecular compounds (“small molecules”), respectively, or combinations thereof.

According to a further embodiment, the hole-conducting layer of the basic color unit and/or each of the color units each comprise at least one hole injection layer, a hole transport layer or a combination thereof. In particular, both doped layers of molecular compounds and doped layers of electrically conductive polymers may be used as hole transport or hole injection layer, respectively. For example, tertiary amines, carbazole derivatives, conductive polyaniline or polyethylene dioxythiophene can be advantageous as materials, particularly for the hole transport layer.

According to a further embodiment, the electron-conductive layers of the basic color unit and/or each of the color units each comprise at least one electron injection layer, electron transport layer or a combination thereof. For example, the electron-conductive layer may comprise an electron transport layer, which comprise 2,9-dimethyl-4,7-diphenyl-1,10-phenanthrolin (BCP) or 4,7-diphenyl-1,10-phenanthrolin (BPhen). Said material may preferably comprise a dopand, which is selected from Li, Cs₂CO₃, Cs₃Po₄ or a molecular doping.

According to a further embodiment, the light-emitting layers of the basic color unit and/or each of the color units each comprise an electroluminescent material, and very preferably are designed as an electroluminescent layer or electroluminescent layer stack. Materials suitable to that end include materials having a radiation emission due to fluorescence or phosphorescence, for example polyfluorene, polythiophene or polyphenylene, or derivatives, compounds, mixtures or copolymers thereof.

According to a further embodiment, it is provided that in each case one electron-conductive layer and one hole-conductive layer is arranged between vertically neighboring, light-emitting layers of the basic color unit and/or each of the color units. Such a combination for neighboring electron- and hole-conductive layers, between which an un-doped layer acting as a charge carrier generation zone may be arranged, can also be called a charge generation layer (CGL). Such a charge generation layer may also be arranged between the basic color unit and the additional basic color unit or between the plurality of color units and the covering color unit.

A suitable selection of the materials in the organic light-emitting layers of the basic color unit and/or each of the color units allows generating monochrome or multicolor or, for example, white light. Multicolor or white light can be generated by the combination of various organic light-emitting materials in the basic color unit and/or each of the color units.

The following color combinations are mentioned merely by way of example:

the basic color unit emits green light, the plurality of color units emit red and blue light with different increased or suppressed spectral sub-ranges.

the basic color unit emits red and green light, the plurality of color units emit blue light with different increased or suppressed spectral sub-ranges.

the basic color unit emits red light and an additional basic color unit emits green light, the plurality of color units emit blue light with different increased or suppressed spectral sub-ranges.

the basic color unit emits white light, which is slightly modified by the plurality of color units in the spectral composition.

A person skilled in the art will recognize that the inventive arrangement of a plurality of color units on at least one basic color unit allows many options of color combinations or color nuances in the component.

### BRIEF DESCRIPTION OF THE DRAWINGS

Further advantages, advantageous embodiments and developments result from the exemplary embodiments described in the following in conjunction with the figures.

The figures show in:

FIG. 1 a schematic illustration of an organic light emitting component according to a first exemplary embodiment,

FIG. 2 a schematic illustration of an organic light-emitting component according to a second exemplary embodiment, and

FIG. 3 a schematic illustration of an organic light-emitting component according to a third exemplary embodiment.

Throughout the exemplary embodiments and the Figures, same, equivalent or similar elements may have the same reference numerals, respectively. The illustrated elements and their size ratios are not to be considered to scale, individual elements such as layers, elements, components and regions may rather be shown in an exaggerated size for a better understanding and illustration.

### DETAILED DESCRIPTION OF ILLUSTRATIVE EMBODIMENTS

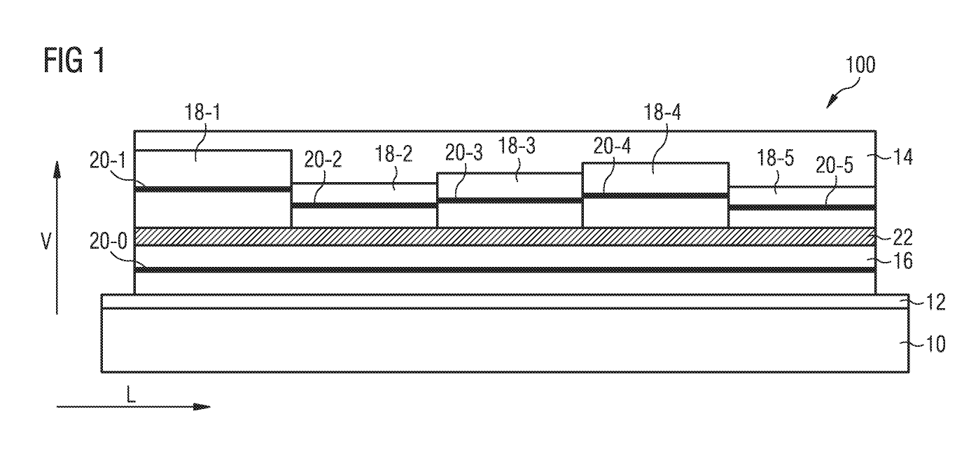

FIG. 1 shows a schematic illustration of an organic light-emitting component according to a first exemplary embodiment. The organic light-emitting component, generally indicated by 100, comprises a transparent substrate 10, on which an anode 12 having a transparent design is formed in a large-area manner. A basic color unit 16 is arranged on the anode 12, said basic color unit being designed for emitting green light, for example. A plurality of color units 18-1, 18-2, 18-3, 18-4 and 18-5 is arranged on the basic color unit 16, said color units being offset to one another in a lateral direction L and having different heights, i.e. having different dimensions in a vertical direction V. Five color units 18-1, 18-2, 18-3, 18-4, 18-5 are illustrated in the drawing, however, less than five, for example two, or more than five color units may be provided. The color units 18-1, 18-2, 18-3, 18-4, 18-5 are designed for emitting either red or blue light with a desired accentuation in certain color ranges. A reflective cathode 14 is arranged on top of the plurality of color units 18-1, 18-2, 18-3, 18-4, 18-5.

Both the basic color unit 16 and the plurality of color units 18-1, 18-2, 18-3, 18-4 and 18-5 comprise different organic functional layers, including in each case at least one light-emitting layer 20-0, 20-1, 20-2, 20-3, 20-4, 20-5. The organic light-emitting layers 20-1, 20-2, 20-3, 20-4, 20-5 of the plurality of color units 18-1, 18-2, 18-3, 18-4 and 18-5 have different distances to the reflective cathode 14 in the vertical direction, thus adjusting the micro cavities assigned to the respective color units 18-1, 18-2, 18-3, 18-4, 18-5 individually in terms of their geometric boundary conditions. This allows increasing or reducing the radiation of certain color components of the emitted red or blue light, respectively, and optimizing the color rendering index of the light radiated by the component 100.

A charge generation layer 22 is arranged between the basic color unit 16 and the plurality of color units 18-1, 18-2, 18-3, 18-4 and 18-5, said layer being illustrated as a hatched area in FIG. 1.

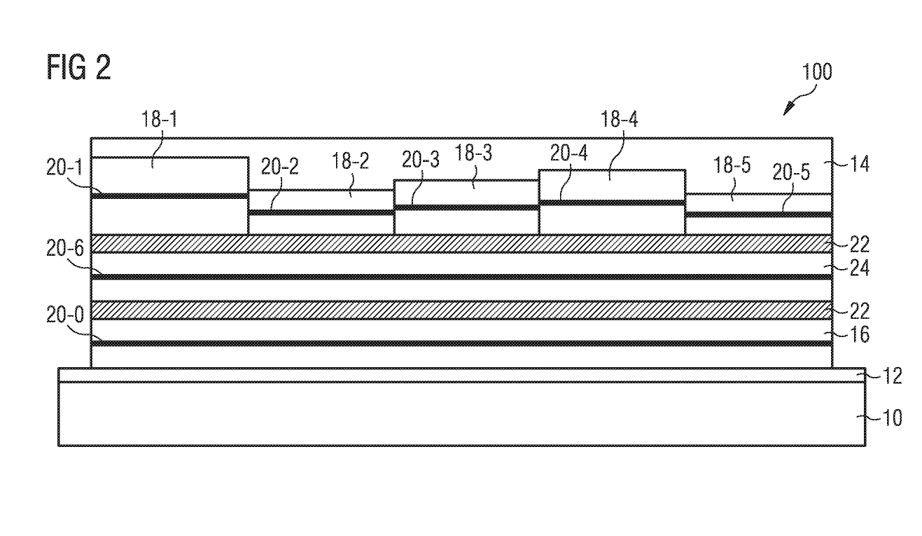

FIG. 2 shows a schematic illustration of an organic light-emitting component according to a second exemplary embodiment. In contrast to the first exemplary embodiment, an additional second basic color unit 24 is provided between the basic color unit 16 and the plurality of color units 18-1, 18-2, 18-3, 18-4 and 18-5, said additional basic color unit preferably emitting light of a wavelength range different than that of the first basic color unit. For example, the basic color unit 16 may be designed for emitting green light, and the second basic color unit 24 may be designed for emitting red light. To that end, the second basic color unit 24 comprises an organic light-emitting layer 20-6. The plurality of color units 18-1, 18-2, 18-3, 18-4 and 18-5 in the second exemplary embodiment are designed for emitting blue light with different color nuances. Again, a charge generation layer 22 is provided between the first basic color unit 16 and the second basic color unit 24.

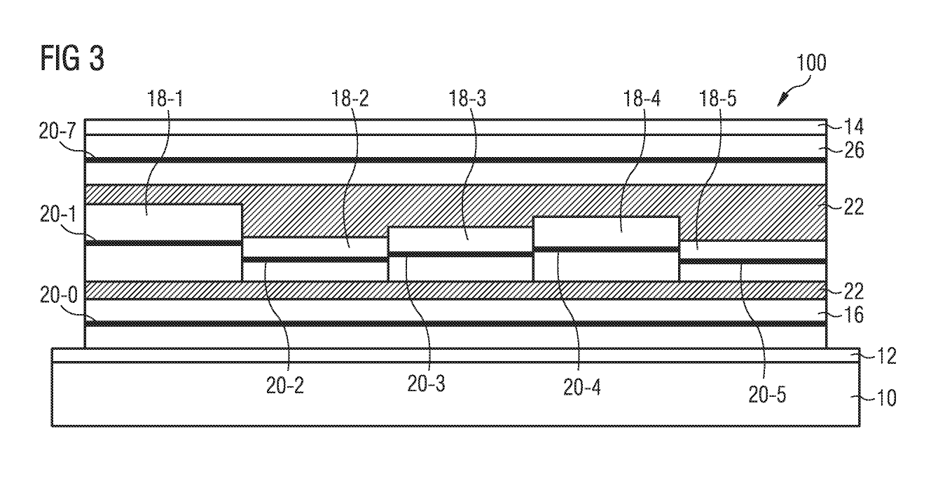

FIG. 3 shows a schematic illustration of an organic light-emitting component according to a third exemplary embodiment. In contrast to the first exemplary embodiment, a covering color unit 26 is arranged between the plurality of color units 18-1, 18-2, 18-3, 18-4 and 1-5 and the reflective cathode 14, said covering color unit being designed for emitting red light, similar to the second basic color unit 24 in the second exemplary embodiment being designed to emit red light. To that end, the covering color unit 26 comprises an organic light-emitting layer 20-7. Again, the plurality of color units 18-1, 18-2 18-3, 18-4 and 18-5 is designed for emitting blue light with different color nuances. Again, a charge generation layer 22 is arranged between the plurality of color units 18-1, 18-2, 18-3, 18-4 and 18-5 and the covering color unit 26.

The invention is not limited by the description in conjunction with the exemplary embodiments. The invention rather comprises any new feature as well as any combination of features, particularly including any combination of features in the patent claims, even though said feature or said combination per se is not explicitly mentioned in the patent claims or exemplary embodiments.

1-14. (canceled)

15. An organic light-emitting component comprising:
a substrate; and
at least one layer sequence arranged on the substrate and suitable for generating electromagnetic radiation, the at least one layer sequence comprising:
at least one first electrode area arranged on the substrate;
at least one second electrode area arranged on the first electrode area;
a basic color unit arranged between the first electrode area and the second electrode area; and
a plurality of color units arranged between the basic color unit and the first or second electrode area, wherein the plurality of color units is arranged laterally offset to one another, and wherein the basic color unit and each of the plurality of color units respectively comprises at least one organic light-emitting layer.

16. The component according to claim 15, wherein the organic light-emitting layer of the basic color unit is designed to generate an electromagnetic radiation of a first wavelength range and each of the organic light-emitting layers of the plurality of color units is designed to generate electromagnetic radiation of a wavelength range that is respectively different from the first wavelength range.

17. The component according to claim 15, wherein the organic light-emitting layers of the plurality of color units are designed to generate electromagnetic radiation of wavelength ranges that are different from one another.

18. The component according to claim 15, wherein wavelength ranges assigned to the basic color unit and to the plurality of color units do not overlap with one another.

19. The component according to claim 15, wherein the plurality of color units has different heights.

20. The component according to claim 15, wherein the organic light-emitting layers of the plurality of color units are arranged in different planes, respectively.

21. The component according to claim 15, wherein at least one charge-producing layer is arranged between the plurality of color units and the basic color unit.

22. The component according to claim 15, wherein the first electrode area or the second electrode area is designed to be reflective.

23. The component according to claim 15, wherein the first electrode area, the second electrode area and the basic color unit each have an area of greater than or equal to one square millimeter.

24. The component according to claim 15, wherein a distance of two neighboring color units from one another is less than 1 mm.

25. The component according to claim 15, wherein the color units are designed in a strip and are arranged parallel to one another.

26. The component according to claim 15, wherein the color units are arranged in a two-dimensional, right-angled or hexagonal grid.

27. The component according to claim 15, further comprising at least one additional basic color unit, wherein the at least one addition basic color unit is arranged between the plurality of color units and the basic color unit, and wherein the at least one additional basic color unit comprises at least one organic light-emitting layer.

28. The component according to claim 15, wherein the plurality of color units is arranged between the basic color unit and at least one covering color unit, which comprises at least one organic light-emitting layer.

29. An organic light-emitting component comprising:
a substrate, and
at least one layer sequence arranged on the substrate and suitable for generating electromagnetic radiation, the at least one layer sequence comprising:
at least one first electrode area arranged on the substrate;
at least one second electrode area arranged on the first electrode area;
a basic color unit arranged between the first electrode area and the second electrode area; and
a plurality of color units arranged between the basic color unit and the first or second electrode area,
wherein the plurality of color units is arranged laterally offset to one another,
wherein the basic color unit and each of the plurality of color units respectively comprise at least one organic light-emitting layer, and
wherein a height of a highest color unit and a height of a least high color unit are different from one another by at least 5 nm.

30. An organic light-emitting component comprising:
a substrate; and
at least one layer sequence arranged on the substrate and suitable for generating electromagnetic radiation, the at least one layer sequence comprising:
at least one first electrode area arranged on the substrate;
at least one second electrode area arranged on the first electrode area;
a basic color unit arranged between the first electrode area and the second electrode area; and
a plurality of color units arranged between the basic color unit and the first or second electrode area,
wherein the plurality of color units is arranged laterally offset to one another,
wherein the basic color unit and each of the plurality of color units respectively comprise at least one organic light-emitting layer,
wherein the plurality of color units has different heights, and
wherein the organic light-emitting layers of the plurality of color units are arranged in different planes, respectively.
